(19) United States
(12) Patent Application Publication
(10) Pub. No.: US 2026/0293748 A1
(43) Pub. Date: Sep. 24, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Keigo SATO, Nagano (JP)

(21) Appl. No.: 19/566,402

(22) Filed: Mar. 13, 2026

(30) Foreign Application Priority Data
Mar. 19, 2025 (JP) 2025-044377

(51) Int. Cl. H10W 74/10; H10W 40/20

(52) U.S. Cl. CPC H10W 74/117; H10W 40/231

(57) ABSTRACT

An interconnect substrate includes a core layer having one surface and another surface, a first cavity extending from the one surface to the another surface of the core layer, an electronic component mounting pad disposed on the another surface of the core layer and having a first surface serving as an end surface of the first cavity, and an electronic component disposed on the first surface in the first cavity.

### CROSS-REFERENCE TO RELATED APPLICATIONS

The present application is based on and claims priority to Japanese Patent Application No. 2025-044377 filed on March 19, 2025, with the Japan Patent Office, the entire contents of which are incorporated herein by reference.

### FIELD

The disclosures herein generally relate to interconnect substrates and methods of making an interconnect substrate.

### BACKGROUND

An interconnect substrate as known in the art may have a cavity penetrating a core layer, with an electronic component disposed in the cavity. Interconnect layers and insulating layers are provided on one surface and the other surface of the core layer. For example, a part of one of the insulating layers extends into the cavity to encapsulate the electronic component. Since some electronic components embedded in an interconnect substrate generate heat during operation, improvement of heat dissipation is required.

### Related-Art Document

### Patent Document

Patent Document 1 Japanese Laid-open Patent Publication No. 2011-216740

### SUMMARY

According to an aspect of the embodiment, an interconnect substrate includes a core layer having one surface and another surface, a first cavity extending from the one surface to the another surface of the core layer, an electronic component mounting pad disposed on the another surface of the core layer and having a first surface serving as an end surface of the first cavity, and an electronic component disposed on the first surface in the first cavity.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating an example of an interconnect substrate according to a first embodiment;

FIGS. 2A through 2C are drawings illustrating an example of a manufacturing process of the interconnect substrate according to the first embodiment;

FIGS. 3A and 3B are drawings illustrating the example of the manufacturing process of the interconnect substrate according to the first embodiment;

FIGS. 4A through 4C are drawings illustrating the example of the manufacturing process of the interconnect substrate according to the first embodiment;

FIGS. 5A through 5C are drawings illustrating the example of the manufacturing process of the interconnect substrate according to the first embodiment;

FIGS. 6A and 6B are drawings illustrating the example of the manufacturing process of the interconnect substrate according to the first embodiment;

FIGS. 7A and 7B are drawings illustrating the example of the manufacturing process of the interconnect substrate according to the first embodiment;

FIG. 8 is a cross-sectional view illustrating an example of an interconnect substrate according to a first variation of the first embodiment; and

FIG. 9 is a cross-sectional view illustrating an example of an interconnect substrate according to the second variation of the first embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### Structure of Interconnect Substrate

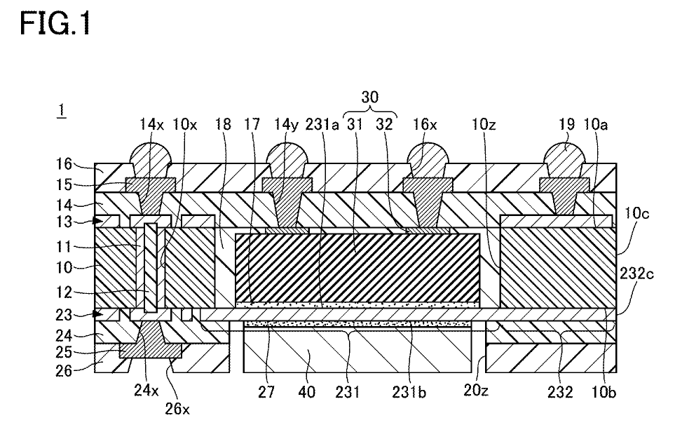

FIG. 1 is a cross-sectional view illustrating an example of an interconnect substrate according to a first embodiment. Referring to FIG. 1, an interconnect substrate 1 is configured such that interconnect layers and insulating layers are laminated on both surfaces of a core layer 10.

Specifically, the interconnect substrate 1 includes an interconnect layer 13, an insulating layer 14, an interconnect layer 15, and a solder resist layer 16 sequentially laminated on a first surface 10a of the core layer 10. On a second surface 10b of the core layer 10, an interconnect layer 23, an insulating layer 24, an interconnect layer 25, and a solder resist layer 26 are sequentially laminated. The numbers of interconnect layers and insulating layers laminated on the first surface 10a and the second surface 10b of the core layer 10 are not limited to the example illustrated in FIG. 1.

In the present embodiment, for convenience, the solder resist layer 16 side of the interconnect substrate 1 is referred to as an upper side or a first side, and the solder resist layer 26 side is referred to as a lower side or a second side. The surface of a portion oriented in the same direction as the solder resist layer 16 side is referred to as a first surface or an upper surface, and the surface of the portion oriented in the same direction as the solder resist layer 26 side is referred to as a second surface or a lower surface. However, the interconnect substrate 1 may be positioned upside down when used, or may be arranged at any angle. The plan view refers to the view of an object as seen from the direction normal to the first surface 10a of the core layer 10, and the plan shape refers to the shape of an object as seen from the direction normal to the first surface 10a of the core layer 10.

The core layer 10 may be, for example, a glass epoxy substrate formed by impregnating a glass cloth with an insulating resin such as an epoxy-based resin. Alternatively, the core layer 10 may be a substrate formed by impregnating a woven fabric or a nonwoven fabric of fiber such as glass fiber, carbon fiber, or aramid fiber with an epoxy-based resin or the like. The thickness of the core layer 10 is, for example, in the range of approximately 60 to 1600 μm. The core layer 10 has through holes 10x extending through the core layer 10 in the thickness direction. The plan shape of each of the through holes 10x is, for example, circular.

The interconnect layer 13 is disposed on the first surface 10a of the core layer 10. The interconnect layer 23 is disposed on the second surface 10b of the core layer 10. The interconnect layer 13 and the interconnect layer 23 are electrically connected by through interconnects 11 formed in the through holes 10x. In the illustrated example, a resin body 12 fills the central inner space of each through interconnect 11. The resin body 12 is cylindrical, for example, and has an upper end extending into the interconnect layer 13 and a lower end extending into the interconnect layer 23. The through interconnects 11 may not have the resin bodies 12. In this case, the through holes 10x are each fully filled with the through interconnect 11.

Each of the interconnect layers 13 and 23 is patterned in a predetermined plan shape. The interconnect layer 23 includes an electronic component mounting pad 231 and an interconnect 232 electrically connected to the electronic component mounting pad 231. The interconnect layer 23 may include additional pads and/or interconnects.

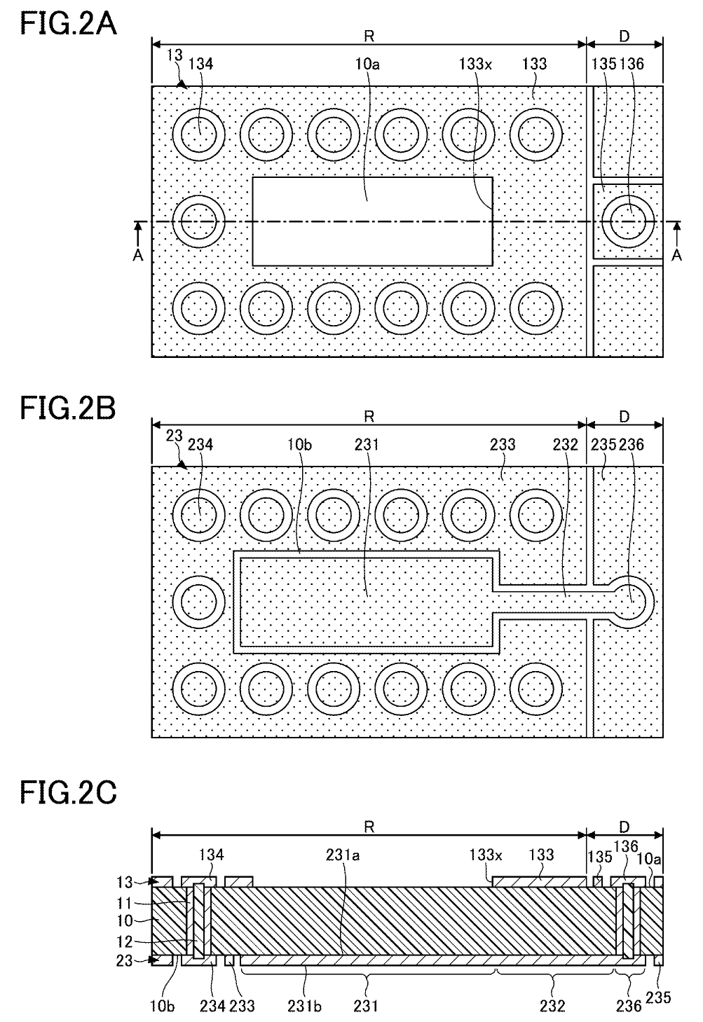

The electronic component mounting pad 231 has a first surface 231a and a second surface 231b opposite the first surface 231a. The end surface 232c of the interconnect 232 is exposed on the same side as the side surface 10c of the core layer 10. The end surface 232c of the interconnect 232 is flush with the side surface 10c of the core layer 10, for example. An example of the plan shapes of the electronic component mounting pad 231 and the interconnect 232 is illustrated in FIG. 2B, which will be described later.

The interconnect layers 13 and 23 and the through interconnects 11 may be made of, for example, copper (Cu) or the like. The thicknesses of the interconnect layers 13 and 23 are, for example, in the range of approximately 25 to 45 μm. The interconnect layer 13, the interconnect layer 23, and the through interconnects 11 may be seamlessly formed.

The interconnect substrate 1 has a first cavity 10z which extends through the core layer 10 from the first surface 10a to the second surface 10b. A part of the first surface 231a of the electronic component mounting pad 231 is in contact with the second surface 10b of the core layer 10 in an area surrounding the first cavity 10z in plan view. A part of the first surface 231a of the electronic component mounting pad 231 is located at the lower opening of the first cavity 10z to constitute the bottom surface (i.e., end surface) of the first cavity 10z.

In the first cavity 10z, an electronic component 30 is disposed on the first surface 231a of the electronic component mounting pad 231 via an adhesive layer 17. The adhesive layer 17 may be conductive or non-conductive. The adhesive layer 17 is preferably composed of a material having a high thermal conductivity. The adhesive layer 17 may be made of a resin serving as an adhesive and containing an alumina filler or the like.

The electronic component 30 includes a core 31 and electrodes 32 formed on an electrode forming surface of the core 31. The electronic component 30 is arranged face-up in the first cavity 10z, with the electrodes 32 facing the insulating layer 14. The upper surfaces of the electrodes 32 are flush with the first surface 10a of the core layer 10, for example. The height of the upper surface of the core 31 as measured from the second surface 10b of the core layer 10 is lower than the height of the first surface 10a of the core layer 10 as measured from the second surface 10b of the core layer 10. That is, the core 31 is thinner than the core layer 10.

The electronic component 30 may be a passive component or an active component. The electronic component 30 may be, for example, an IPD (integrated passive device), a semiconductor chip, a capacitor, an inductor, a resistor, or the like. The plan shape of the first cavity 10z is, for example, geometrically similar to the plan shape of the electronic component 30, and its size is larger than that of the electronic component 30. A plurality of electronic components 30 may be arranged in the first cavity 10z.

A resin portion 18 is an embedded insulating layer arranged in the first cavity 10z. The resin portion 18 covers the upper surface and the side surfaces of the core 31 of the electronic component 30 in the first cavity 10z. The resin portion 18 does not cover the upper surfaces of the electrodes 32 of the electronic component 30 and covers the side surfaces thereof. The upper surface of the resin portion 18 and the upper surfaces of the electrodes 32 may be flush with the first surface 10a of the core layer 10, for example. The material of the resin portion 18 may be, for example, an insulating resin mainly composed of an epoxy-based resin or a polyimide-based resin.

The insulating layer 14 is disposed on the first surface 10a of the core layer 10 and covers the interconnect layer 13 and the resin portion 18. The material of the insulating layer 14 may be an insulating resin mainly composed of, for example, an epoxy-based resin or a polyimide-based resin. The thickness of the insulating layer 14 may be, for example, in the range of approximately 30 to 40 μm. The insulating layer 14 may contain a filler such as silica (SiO₂).

Via holes 14x are formed in the insulating layer 14 to extend through the insulating layer 14 and reach the upper surface of the interconnect layer 13. The insulating layer 14 also includes via holes 14y that penetrate the insulating layer 14 to reach the upper surfaces of the electrodes 32 of the electronic component 30. The via holes 14x and 14y may each be an inverted truncated conical hole in which the diameter of the opening toward the solder resist layer 16 is larger than the diameter of the opening at the upper surface of the interconnect layer 13 or one of the electrodes 32.

The interconnect layer 15 is disposed on the first side of the insulating layer 14. The interconnect layer 15 includes via interconnects filling the via holes 14x, via interconnects filling the via holes 14y, and an interconnect pattern formed on the upper surface of the insulating layer 14. Portions of the interconnect pattern are electrically connected to the interconnect layer 13 through the via interconnects filling the via holes 14x. Other portions of the interconnect pattern are electrically connected to the electrodes 32 through the via interconnects filling the via holes 14y. The material of the interconnect layer 15 and the thickness of the interconnect pattern may be substantially the same as those of the interconnect layer 13, for example.

The solder resist layer 16 is a protective insulating layer located as the outermost layer on the first side of the interconnect substrate 1, and is formed on the upper surface of the insulating layer 14 so as to cover the interconnect layer 15. The solder resist layer 16 may be formed of, for example, a photosensitive epoxy-based insulating resin or acrylic-based insulating resin. The thickness of the solder resist layer 16 is, for example, in the range of approximately 15 to 35 μm.

The solder resist layer 16 has openings 16x. The openings 16x penetrate the solder resist layer 16 to reach the upper surface of the interconnect layer 15. The interconnect layer 15 located within the openings 16x may be used as pads for electrical connections with an electronic component such as a semiconductor chip, for example.

On the surface of the interconnect layer 15 exposed in the opening 16x, a metal layer may be formed, or an organic coating may be formed by applying an antioxidant treatment such as organic solderability preservative (OSP) treatment. Examples of the metal layer include an Au layer, a Ni/Au layer (a metal layer formed by laminating a Ni layer and an Au layer in this order), a Ni/Pd/Au layer (a metal layer formed by laminating a Ni layer, a Pd layer, and an Au layer in this order), and a Sn layer.

In the illustrated example, external connection terminals 19 filling the openings 16x and projecting from the upper surface of the solder resist layer 16 are provided on the interconnect layer 15 located within the openings 16x. The external connection terminals 19 are, for example, solder bumps. The material of the solder bumps may be, for example, an alloy containing Pb, an alloy of Sn and Cu, an alloy of Sn and Ag, an alloy of Sn, Ag and Cu, or the like. The external connection terminals 19 may be provided when required.

The insulating layer 24 is disposed on the second surface 10b of the core layer 10 to cover the interconnect layer 23. The material and thickness of the insulating layer 24 may be substantially the same as those of the insulating layer 14, for example. The insulating layer 24 may contain a filler such as silica (SiO₂).

Via holes 24x are formed in the insulating layer 24 to extend through the insulating layer 24 and reach the lower surface of the interconnect layer 23. The via holes 24x may each be a truncated conical hole in which the diameter of the opening toward the solder resist layer 26 is larger than the diameter of the opening at the lower surface of the interconnect layer 23.

The interconnect layer 25 is disposed on the second side of the insulating layer 24. The interconnect layer 25 includes via interconnects filling the via holes 24x and an interconnect pattern formed on the lower surface of the insulating layer 24. The interconnect pattern is electrically connected to the interconnect layer 23 through the via interconnects filling the via holes 24x. The material of the interconnect layer 25 and the thickness of the interconnect pattern may be, for example, substantially the same as those of the interconnect layer 23.

The solder resist layer 26 is a protective insulating layer located as the outermost layer on the second side of the interconnect substrate 1, and is formed on the lower surface of the insulating layer 24 to cover the interconnect layer 25. The material and thickness of the solder resist layer 26 may be substantially the same as those of the solder resist layer 16, for example. The solder resist layer 26 has openings 26x, and portions of the lower surface of the interconnect layer 25 are exposed within the openings 26x. The plan shape of each of the openings 26x may be, for example, circular. The interconnect layer 25 exposed in the openings 26x may be used as pads for electrical connections to a mounting substrate such as a motherboard. If necessary, a metal layer of the kind previously described may be formed on the lower surface of the interconnect layer 25 exposed in the openings 26x, or an oxidation prevention treatment such as OSP treatment may be applied.

The interconnect substrate 1 has a second cavity 20z which penetrates the solder resist layer 26 and the insulating layer 24 to expose the second surface 231b of the electronic component mounting pad 231. The second cavity 20z may be arranged at a position overlapping with the first cavity 10z in plan view. The plan shape of the second cavity 20z may be, for example, rectangular. In plan view, the size of the second cavity 20z may be the same as the size of the first cavity 10z, or may be larger or smaller than the size of the first cavity 10z.

The interconnect substrate 1 includes a heatsink component 40 disposed on the second surface 231b of the electronic component mounting pad 231 in the second cavity 20z. The heatsink component 40 may be disposed on the second surface 231b via an adhesive layer 27. The adhesive layer 27 may be conductive or non-conductive. The adhesive layer 27 is preferably made of a material having a high thermal conductivity. The adhesive layer 27 may be made of a resin serving as an adhesive and containing an alumina filler or the like.

The plan shape of the heatsink component 40 may be, for example, rectangular. A space, for example, is formed between the side surfaces of the heatsink component 40 and the inner surfaces of the second cavity 20z. The heatsink component 40 may be made of a material having good thermal conductivity, such as copper or a copper alloy. The lower surface of the heatsink component 40 is flush with the lower surface of the solder resist layer 26, for example. Alternatively, the lower surface of the heatsink component 40 may project or be recessed relative to the lower surface of the solder resist layer 26.

As described heretofore, the interconnect substrate 1 is configured such that the electronic component 30 is disposed on the first surface 231a of the electronic component mounting pad 231, and the heatsink component 40 is disposed on the second surface 231b of the electronic component mounting pad 231. The heat generated in the electronic component 30 during the operation of the electronic component 30 is diffused by the electronic component mounting pad 231 and dissipated to the outside via the heatsink component 40, thereby effectively improving the heat dissipation of the interconnect substrate 1. This arrangement reduces the likelihood of disturbance of electric signals resulting from thermal runaway, thereby enabling the electronic component 30 to fully exhibit its inherent performance characteristics.

### Method of Making Interconnect Substrate

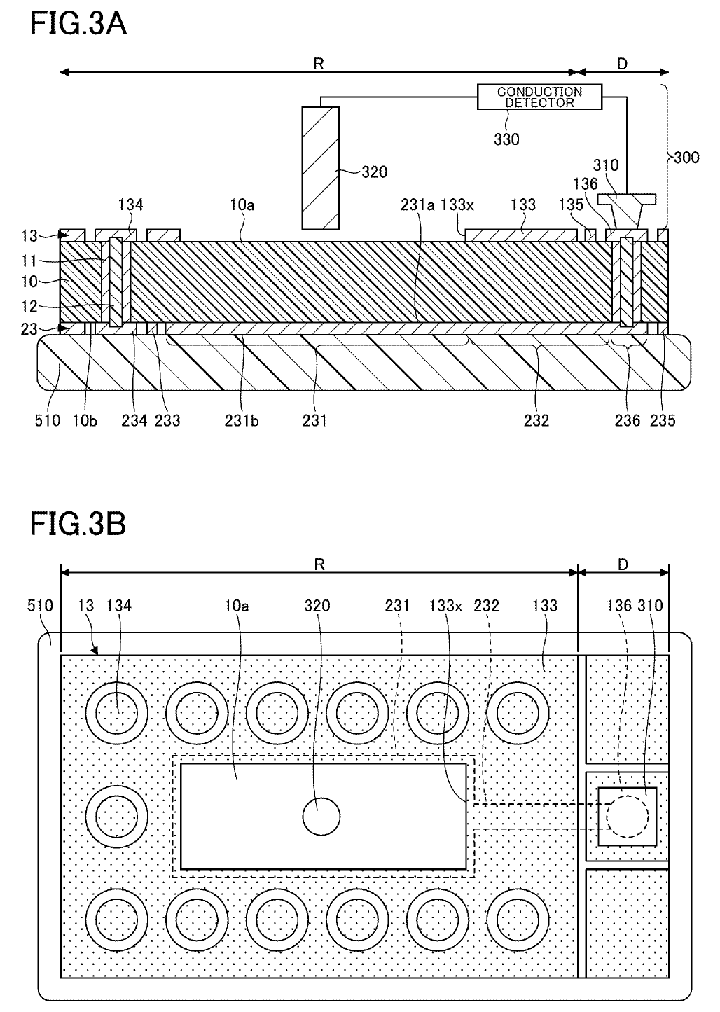

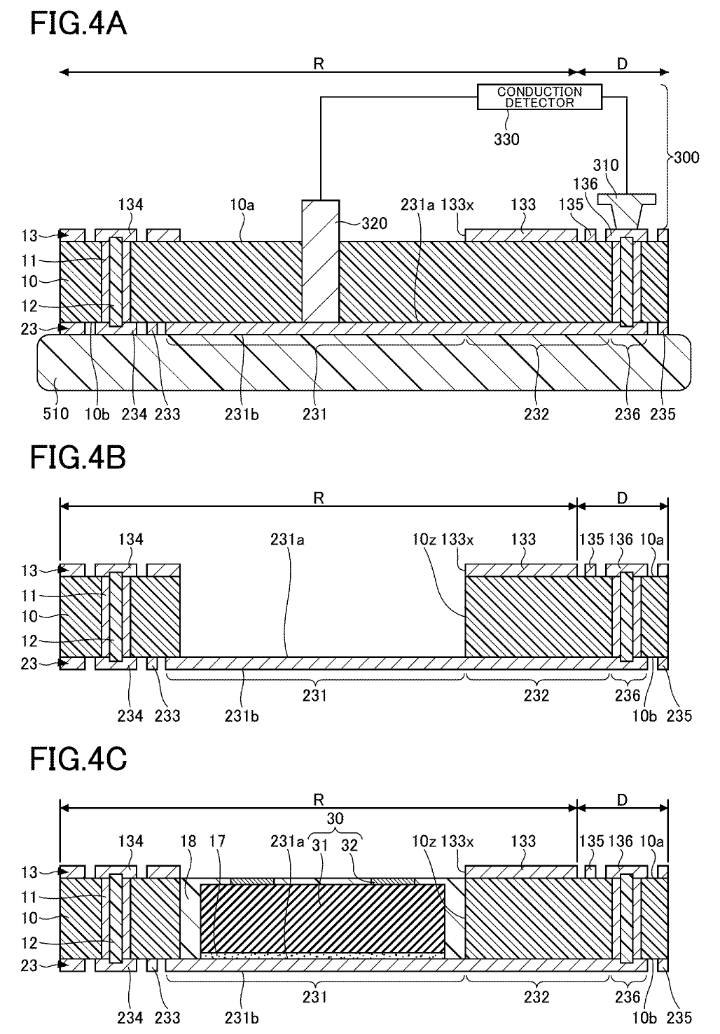

FIGS. 2A through 2C to FIGS. 7A and 7B are drawings illustrating an example of a manufacturing process of the interconnect substrate according to the first embodiment. FIG. 2A is a plan view, FIG. 2B is a bottom view, and FIG. 2C is a cross-sectional view along line A-A of FIG. 2A. FIG. 3A is a cross-sectional view taken at the same position as FIGS. 2C and FIG. 3B, is a plan view of FIG. 3A. FIGS. 4A through 4C to FIGS. 7A and 7B are cross-sectional views taken at the same position as FIG. 2C.

First, the step illustrated in FIGS. 2A to 2C first prepares a core layer 10 having an interconnect region R which is diced to become an interconnect substrate and a cutting region D which is severed at the time of dicing. Then, an interconnect layer 13 is formed in the interconnect region R and the cutting region D on the first surface 10a of the core layer 10. Further, an interconnect layer 23 is formed in the interconnect region R and the cutting region D on the second surface 10b of the core layer 10. Through holes 10x extending through the core layer 10 are also formed, and through interconnects 11 and resin bodies 12 are formed in the through holes 10x.

Specifically, for example, a laminated plate is prepared that includes the core layer 10 and un-patterned solid copper foils on the first and second surfaces thereof. Then, the through holes 10x penetrating the core layer 10 and the copper foil on each surface is formed in the prepared laminated plate by laser processing using a CO₂ laser or the like. According to need, desmearing is performed to remove the resin residue of the core layer 10 adhering to the inner wall surfaces of the through holes 10x.

Next, a seed layer (copper or the like) covering the copper foil on each surface and the inner wall surfaces of the through holes 10x is formed by, for example, electroless plating or sputtering, and an electroplated layer (copper or the like) is formed on the seed layer by an electroplating method using the seed layer as a current supply path. After this process, the through holes remain and are surrounded by the electroplated layer, so that an epoxy resin or the like is injected into the through holes to form the resin bodies 12. This arrangement forms the through interconnects 11 by filling the through holes 10x with the electroplated layer formed on the seed layer, and also forms the resin bodies 12 inside the through interconnects 11.

Metal layers made of copper or the like are formed on both ends of the through interconnects 11 and the resin bodies 12 at both surfaces of the core layer 10 by electroless plating and electroplating. The interconnect layers 13 and 23 are formed on the first surface 10a and the second surface 10b of the core layer 10, respectively, each as a laminate of a copper foil, a seed layer, an electroplated layer, and a metal layer. After that, the interconnect layers 13 and 23 are patterned into predetermined plan shapes by a subtractive method or the like.

The interconnect layer 13 is formed to include an interconnect 133, a plurality of pads 134, an interconnect 135, and one pad 136. The interconnect 133 and the pads 134 are formed in an interconnect region R, and the interconnect 135 and the pad 136 are formed in the cutting region D. The interconnect 133 may be arranged so as to surround each pad 134. The interconnect 133 has an opening 133x. The first surface 10a of the core layer 10 is exposed in the opening 133x. None of the interconnect 133 and the pads 134 is electrically connected to either the interconnect 135 or the pad 136.

The interconnect layer 23 is formed to include an electronic component mounting pad 231, an interconnect 232, an interconnect 233, a plurality of pads 234, an interconnect 235, and one pad 236. The electronic component mounting pad 231, the interconnect 233, and the pads 234 are formed in the interconnect region R, and the interconnect 235 and the pad 236 are formed in the cutting region D. The interconnect 232 extends from the interconnect region R to the cutting region D to electrically connect the electronic component mounting pad 231 and the pad 236. The interconnect 233 may be arranged so as to surround the electronic component mounting pad 231, a part of the interconnect 232, and the pads 234. The interconnect 235 may be arranged so as to surround a part of the interconnect 232 and the pad 236. None of the electronic component mounting pad 231, the interconnect 232, and the pad 236 is electrically connected to any of the interconnect 233, the pads 234, and the interconnect 235.

The pads 134 and the pads 234 are formed at overlapping positions in plan view, and are electrically connected via the through interconnects 11. The pad 136 and the pad 236 are formed at an overlapping position in plan view and are electrically connected via one of the through interconnects 11. That is, the pad 136 is electrically connected to the electronic component mounting pad 231 via the through interconnect 11, the pad 236, and the interconnect 232. The opening 133x and the electronic component mounting pad 231 are formed at an overlapping position in plan view. The interconnects 133, 135, 233, and 235 need not be formed. Alternatively, interconnects other than the interconnects 133, 135, 233, and 235 may be formed.

In the steps illustrated in FIGS. 3A to 4B, a first cavity 10z, which penetrates from the first surface 10a to the second surface 10b of the core layer 10 and exposes the first surface 231a of the electronic component mounting pad 231, is formed in a portion of the core layer 10 exposed within the opening 133x. The first cavity 10z is formed, for example, by a routing process (rough machining) utilizing a router bit. The first cavity 10z may be formed by laser machining using a CO₂ laser or the like. The following is an example of forming the first cavity 10z by a routing process.

First, as illustrated in FIGS. 3A and 3B, the structure illustrated in FIG. 2C is placed on a support 510 and fixed to the support 510, for example, by vacuum suction. Further, a cutting jig 300 including a conduction jig 310, a conductive cutting tool 320, and a conduction detector 330 for detecting conduction between the conduction jig 310 and the cutting tool 320 is prepared. The conduction jig 310 is brought into contact with the pad 136 serving as a conduction terminal. The conduction jig 310 has a projection on the side facing the pad 136, which ensures stable electrical connection between the conduction jig 310 and the pad 136. The projection may have a spring property. This arrangement ensures more stable electrical connection between the conduction jig 310 and the pad 136. The conduction jig 310 may have a plurality of projections on the side facing the pad 136. This arrangement ensures more stable electrical connection between the conduction jig 310 and the pad 136. Examples of the conduction jig 310 include a metal jig made of copper, aluminum, iron, or the like. Examples of the cutting tool 320 include a metal router bit having a substantially circular shape in plan view. Examples of the conduction detector 330 include an electronic device including a CPU (central processing unit).

As illustrated in FIG. 4A, the cutting tool 320 is arranged at a position overlapping at least a part of the electronic component mounting pad 231 in plan view. For example, the cutting tool 320 is arranged at the center of the region where the first cavity 10z is to be formed in plan view. Then, the cutting tool 320 is rotated around its longitudinal center axis. The rotating cutting tool 320 is lowered in the direction perpendicular to the first surface 10a of the core layer 10 while cutting the core layer 10, and the lowering is stopped when the conduction detector 330 detects conduction between the conduction jig 310 and the cutting tool 320. The electronic component mounting pad 231 and the pad 136 are electrically connected through the core layer 10. With this arrangement, when the cutting tool 320 comes in contact with the electronic component mounting pad 231, the conduction detector 330 detects conduction between the conduction jig 310 and the cutting tool 320, which causes the lowering of the cutting tool 320 to stop at that position.

In the state where the conduction detector 330 is detecting the conduction, the cutting tool 320 is moved in directions parallel to the first surface 10a of the core layer 10 to form the first cavity 10z as illustrated in FIG. 4B. A part of the first surface 231a of the electronic component mounting pad 231 is exposed at the bottom of the first cavity 10z. For example, the first cavity 10z may be formed by gradually moving the cutting tool 320 along a rectangular spiral trajectory in plan view from the center of the region where the first cavity 10z is to be formed to the periphery of the region where the first cavity 10z is to be formed. Here, the state where the conduction detector 330 is detecting the conduction refers to a state where the cutting tool 320 is continuously in contact with the electronic component mounting pad 231. For example, the electronic component mounting pad 231 may have surface undulation or the like. Even an instantaneous loss of the physical contact between the electronic component mounting pad 231 and the cutting tool 320 automatically causes the cutting tool 320 to move downward to the electronic component mounting pad 231, thereby maintaining contact with the electronic component mounting pad 231. During formation of the first cavity 10z, it is permissible for the electronic component mounting pad 231 to be partially removed at the first surface 231a.

In the step illustrated in FIG. 4C, an electronic component 30 is arranged on the first surface 231a of the electronic component mounting pad 231 in the first cavity 10z. Specifically, an electronic component 30 having electrodes 32 is arranged face-up on the first surface 231a exposed in the first cavity 10z with the adhesive layer 17 interposed therebetween. The electronic component 30 may be arranged using, for example, a mounter for electronic components. When an electronic component is arranged in a cavity having no bottom surface as in the related-art configuration, a temporary fixing film is attached to the second surface of the core layer to form a bottom surface of the cavity, and the electronic component is arranged on this bottom surface. In contrast, the manufacturing process of the interconnect substrate 1 disclosed herein utilizes the first surface 231a of the electronic component mounting pad 231 as the bottom surface of the first cavity 10z, which is advantageous in that the temporary fixing film is not required.

Subsequently, a resin portion 18 is formed in the first cavity 10z. Specifically, for example, an insulating resin in liquid or paste form is dispensed into the first cavity 10z and cured. Alternatively, an insulating resin film may be used instead of the insulating resin liquid or paste. According to need, the upper surface of the cured resin portion 18 may be polished. The resin portion 18 covers the upper surface and the side surfaces of the core 31 of the electronic component 30 in the first cavity 10z. The resin portion 18 does not cover the upper surfaces of the electrodes 32 of the electronic component 30 and covers the side surfaces thereof. The upper surface of the resin portion 18 and the upper surfaces of the electrodes 32 may be flush with the first surface 10a of the core layer 10, for example.

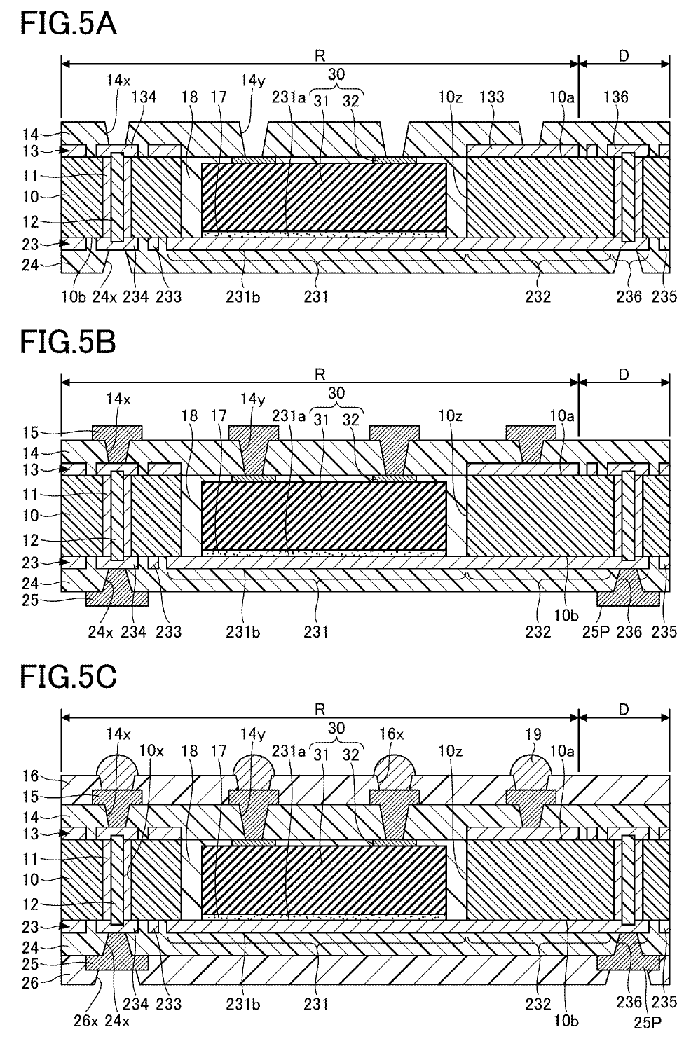

In the step illustrated in FIG. 5A, an insulating layer 14 is formed on the first surface 10a of the core layer 10, and an insulating layer 24 is formed on the second surface 10b of the core layer 10. Specifically, for example, a semi-cured epoxy-based resin film or the like is laminated on the first surface 10a of the core layer 10 so as to cover the interconnect layer 13, the upper surface of the resin portion 18, and the upper surfaces of the electrodes 32, and then cured to form the insulating layer 14. Alternatively, instead of laminating epoxy-based resin film or the like, epoxy-based resin or the like in liquid or paste form may be applied and then cured to form the insulating layer 14. The material and the thickness of the insulating layer 14 are as previously described. Similarly, an insulating layer 24 is formed on the second surface 10b of the core layer 10 to cover the interconnect layer 23.

Then, via holes 14x are formed through the insulating layer 14 to expose the upper surfaces of the interconnect 133 and the pads 134 of the interconnect layer 13. Via holes 14y are also formed through the insulating layer 14 to expose the upper surfaces of the electrodes 32 of the electronic component 30. Via holes 24x are formed through the insulating layer 24 to expose the lower surfaces of the pads 234 and the pad 236. The via holes 14x, 14y, and 24x may be formed by, for example, laser processing using a CO₂ laser or the like. After the via holes 14x, 14y, and 24x are formed, desmearing is preferably performed to remove resin residues adhering to the interconnect layers 13 and 23 exposed at the ends of the via holes 14x, 14y, and 24x and to the surfaces of the electrodes 32.

In the step illustrated in FIG. 5B, an interconnect layer 15 is formed on the first side of the insulating layer 14. The interconnect layer 15 includes via interconnects filling the via holes 14x, via interconnects filling the via holes 14y, and an interconnect pattern formed on the upper surface of the insulating layer 14. A part of the interconnect pattern is electrically connected to the interconnect layer 13 through the via interconnects filling the via holes 14x. The remaining parts of the interconnect pattern are electrically connected to the electrodes 32 through the via interconnects disposed in the via holes 14y.

Further, an interconnect layer 25 is formed on the second side of the insulating layer 24. The interconnect layer 25 includes via interconnects filling the via holes 24x and an interconnect pattern formed on the lower surface of the insulating layer 24. The interconnect pattern is electrically connected to the interconnect layer 23 through the via interconnects filling the via holes 24x. The interconnect layer 25 includes a pad 25P formed in the cutting region D and electrically connected to the pad 236 that is a part of the interconnect layer 23. The interconnect layers 15 and 25 are formed, for example, by a semi-additive method.

In the step illustrated in FIG. 5C, solder resist layers 16 and 26 and external connection terminals 19 are formed. First, the solder resist layer 16 is formed on the upper surface of the insulating layer 14 so as to cover the interconnect layer 15. Further, the solder resist layer 26 is formed on the lower surface of the insulating layer 24 so as to cover the interconnect layer 25. The solder resist layer 16 may be formed, for example, by applying a photosensitive epoxy-based insulating resin in liquid or paste form to the upper surface of the insulating layer 14 so as to cover the interconnect layer 15 by screen printing, roll coating, spin coating, or the like. Alternatively, a photosensitive epoxy-based insulating resin film, for example, may be laminated on the upper surface of the insulating layer 14 so as to cover the interconnect layer 15. The method of forming the solder resist layer 26 is substantially the same as that for forming the solder resist layer 16.

Thereafter, the solder resist layers 16 and 26 are exposed and developed. As a result, openings 16x are formed through the solder resist layer 16 in the interconnect region R to expose the interconnect layer 15. Also, openings 26x for exposing portions of the lower surface of the interconnect layer 25 are formed through the solder resist layer 26 in the interconnect region R. Further, an opening 26x for exposing the lower surface of the pad 25P is formed through the solder resist layer 26 in the cutting region D. If necessary, external connection terminals 19 are provided on the interconnect layer 15 exposed in the openings 16x located in each interconnect region R. The external connection terminals 19 are, for example, solder bumps formed by solder reflow or the like. The pad 25P exposed in the opening 26x is electrically connected to the electronic component mounting pad 231 via the pad 236 and the interconnect 232, serving as a conduction terminal exposed on the solder resist layer 26 side in the cutting region D.

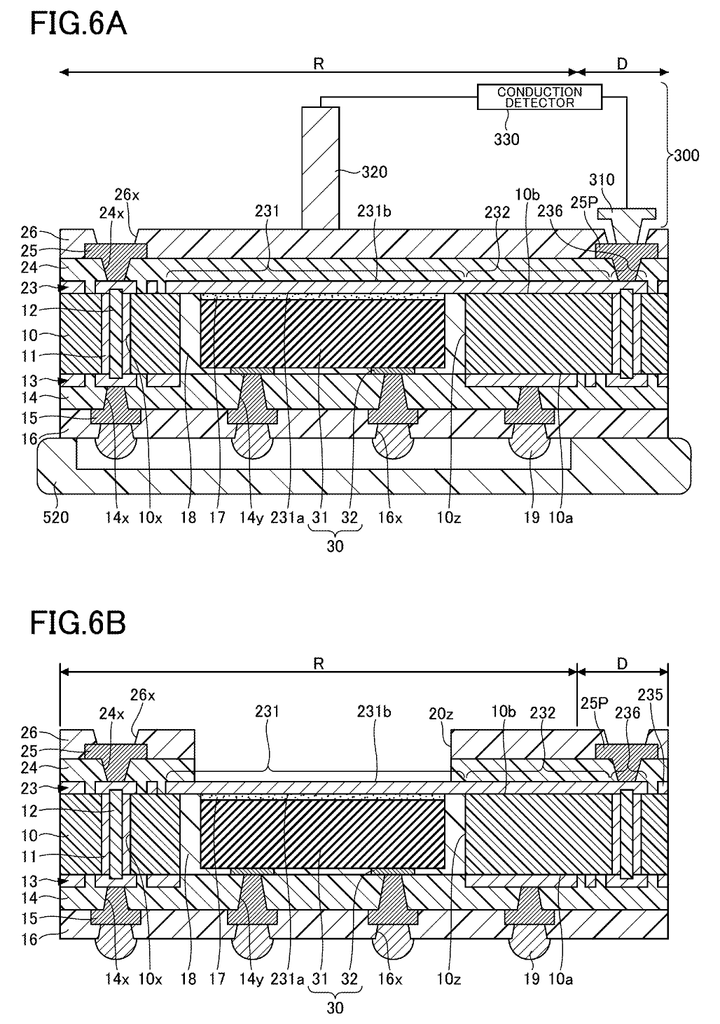

In the step illustrated in FIG. 6A, the structure illustrated in FIG. 5C is flipped upside down and placed on a support 520, and fixed to the support 520, for example, by vacuum suction. The support 520 preferably has a recess for avoiding contact with the external connection terminals 19. Similarly to the step illustrated in FIG. 3A, a cutting jig 300 including a conduction jig 310, a conductive cutting tool 320, and a conduction detector 330 for detecting conduction between the conduction jig 310 and the cutting tool 320 is prepared. The conduction jig 310 is brought into contact with the pad 25P serving as a conduction terminal.

In the step illustrated in FIG. 6B, substantially the same method as in FIGS. 4A and 4B is used to form a second cavity 20z which penetrates the solder resist layer 26 and the insulating layer 24 to expose the second surface 231b of the electronic component mounting pad 231. That is, the cutting tool 320 cuts through the solder resist layer 26 and the insulating layer 24 until the second surface 231b is exposed. In doing so, while controlling the cutting depth of the cutting tool 320 by detecting conduction between the cutting tool 320 and the electronic component mounting pad 231, the cutting tool 320 is moved in the horizontal directions to form the second cavity 20z penetrating the solder resist layer 26 and the insulating layer 24. During formation of the second cavity 20z, it is permissible for the electronic component mounting pad 231 to be partially removed at the second surface 231b. The second cavity 20z may be formed by laser machining using a CO₂ laser or the like.

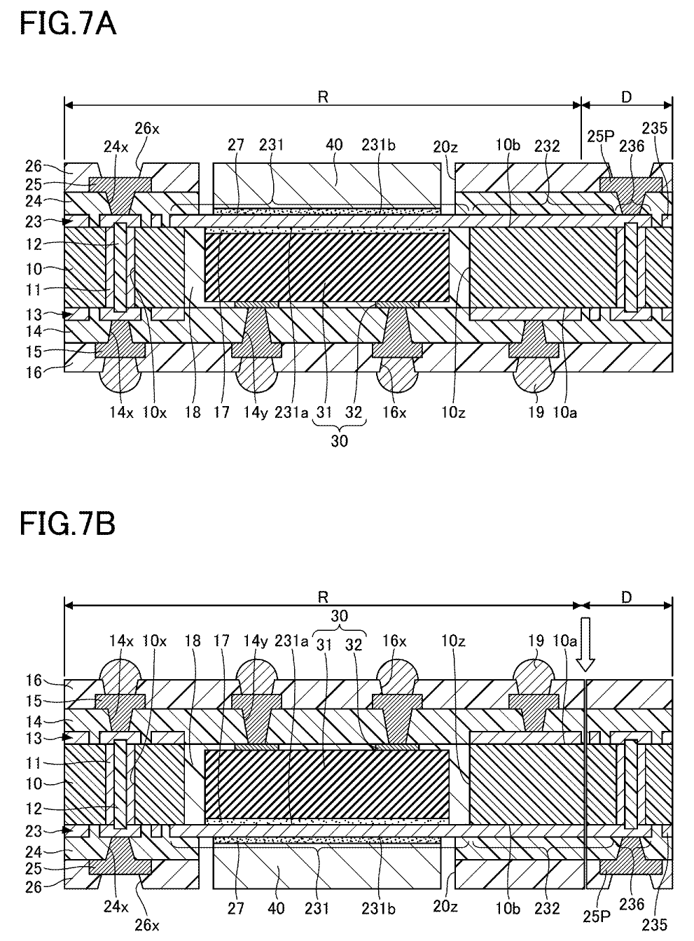

In the step illustrated in FIG. 7A, a heatsink component 40 is disposed on the second surface 231b in the second cavity 20z. Specifically, the heatsink component 40 is fixed to the second surface 231b of the electronic component mounting pad 231 exposed in the second cavity 20z through an adhesive layer 27.

In the step illustrated in FIG. 7B, the structure illustrated in FIG. 7A is cut into pieces at the boundary between the interconnect region R and the cutting region D indicated by the vertical arrow. Specifically, the solder resist layer 16, the insulating layer 14, the core layer 10, the interconnect layer 23, the insulating layer 24, and the solder resist layer 26 are cut at the boundary between the interconnect region R and the cutting region D. Through this process, the interconnect region R and the cutting region D are separated, thereby completing the manufacture of the interconnect substrate 1. For example, a rotary blade or the like may be used for the cutting.

As described above, the manufacturing method of the interconnect substrate 1 utilizes the cutting jig 300 for forming the first cavity 10z. With this arrangement, the core layer 10 is drilled until the first surface 231a of the electronic component mounting pad 231 is exposed, followed by forming the first cavity 10z while maintaining the contact between the cutting tool 320 and the electronic component mounting pad 231. That is, while controlling the cutting depth of the cutting tool 320 by detecting conduction between the cutting tool 320 and the electronic component mounting pad 231, the cutting tool 320 is effectively moved in horizontal directions, thereby enabling the formation of the first cavity 10z having a desired depth. The same applies to the formation of the second cavity 20z.

In addition, the electronic component mounting pad 231, the interconnect 232, and the pad 236 may be used as a common current path for detecting conduction at the time of forming both the first cavity 10z and the second cavity 20z. This arrangement allows the routing of an interconnect, for detecting conduction at the time of forming the first cavity 10z and the second cavity 20z, to be minimized.

As an alternative, the core layer 10 having a plurality of interconnect regions R may be prepared in the steps illustrated in FIGS. 2A to 2C. In this case, an electronic component mounting pad 231 and an interconnect 232 are formed in each of the interconnect regions R, and one pair of pads 136 and 236 may be formed in one cutting region D. The electronic component mounting pads 231 and the interconnects 232 formed in the respective interconnect regions R are connected to the pads 136 and 236 through interconnects formed in the cutting region D.

During the formation of the first cavity 10z and the second cavity 20z, the above-noted arrangement facilitates, through the use of the pads 136 and 236, the detection of conduction between the cutting tool 320 and the electronic component mounting pads 231 formed in the respective interconnect regions R. As a result, the first cavity 10z and the second cavity 20z are effectively formed in the respective interconnect regions R while controlling the cutting depth of the cutting tool 320.

### Variations of First Embodiment

Variations of the first embodiment are directed to examples of interconnect substrates having shapes different from that of the first embodiment. In connection with the variations of the first embodiment, descriptions of the same components as those of the already described embodiment may be omitted.

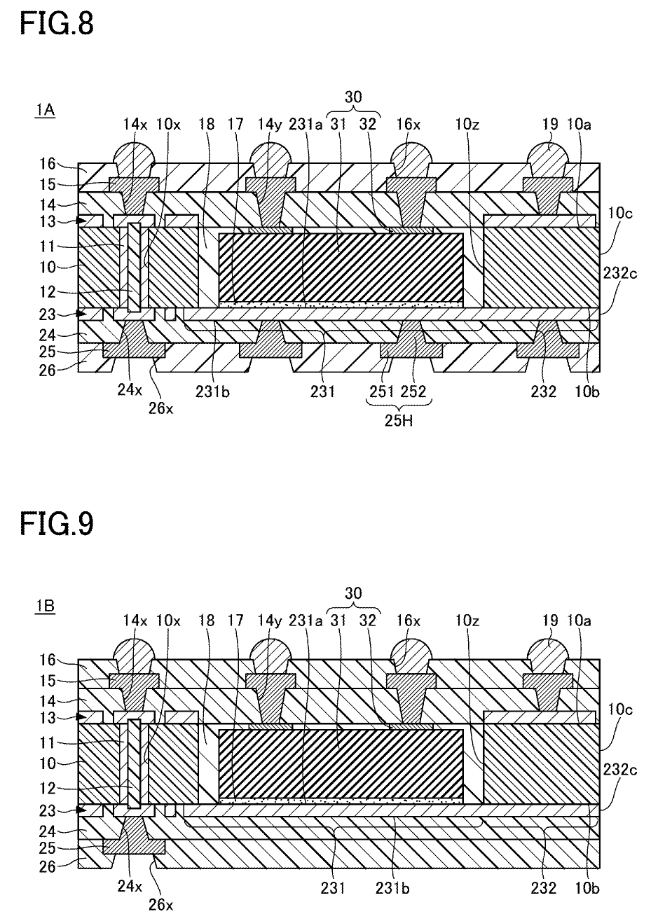

FIG. 8 is a cross-sectional view illustrating an example of an interconnect substrate according to a first variation of the first embodiment. Referring to FIG. 8, an interconnect substrate 1A differs from the interconnect substrate 1 in that it does not have a second cavity 20z, an adhesive layer 27, or a heatsink component 40, and in that the interconnect layer 25 includes heatsink interconnects 25H.

Each of the heatsink interconnects 25H includes a heatsink pad 251 disposed on the second surface of the insulating layer 24, and a via interconnect 252 which extends through the insulating layer 24 to connect the heatsink pad 251 and the electronic component mounting pad 231. The via interconnect 252 is disposed in a via hole 24x. The number of heatsink interconnects 25H may be one or more. In the illustrated example, the interconnect layer 25 includes a plurality of heatsink interconnects 25H. Some of the heatsink interconnects 25H may be connected to the interconnect 232.

The solder resist layer 26 has openings 26x that expose the heatsink pads 251. The solder resist layer 26 is configured such that at least a part of the lower surface of the heatsink pad 251 is exposed, and the entire lower surface of the heatsink pad 251 may optionally be exposed. The solder resist layer 26 may be configured such that the entire lower surface of the heatsink pad 251 and the entire side surface of the heatsink pad 251 are exposed.

As described above, the interconnect substrate 1A is configured such that the heatsink interconnect 25H includes the heatsink pad 251 disposed on the second surface of the insulating layer 24, and the via interconnect 252 which penetrates the insulating layer 24 to connect the heatsink pad 251 and the electronic component mounting pad 231. Heat generated in the electronic component 30 during the operation of the electronic component 30 is diffused by the electronic component mounting pad 231 and dissipated to the outside via the heatsink interconnects 25H, thereby effectively improving the heat dissipation of the interconnect substrate 1A.

FIG. 9 is a cross-sectional view illustrating an example of an interconnect substrate according to the second variation of the first embodiment. Referring to FIG. 9, an interconnect substrate 1B differs from the interconnect substrate 1 in that it does not have a second cavity 20z, an adhesive layer 27, or a heatsink component 40.

In the interconnect substrate 1B, the electronic component 30 is disposed on the first surface 231a of the electronic component mounting pad 231. The heat generated in the electronic component 30 during the operation of the electronic component 30 is diffused by the electronic component mounting pad 231 and dissipated to the outside via the insulating layer 24 and the solder resist layer 26, thereby improving the heat dissipation of the interconnect substrate 1B.

As described above, depending on the required level of heat dissipation performance, the interconnect substrate 1B may be structured to include neither the heatsink component 40 nor the heatsink interconnect 25H. When higher heat dissipation performance is desirable, the heatsink component 40 or the heatsink interconnect 25H is preferably provided.

As an alternative configuration, the interconnect substrate 1B may have a second cavity 20z that penetrates the solder resist layer 26 and the insulating layer 24 to expose the second surface 231b of the electronic component mounting pad 231. Even without the heatsink component 40, the heat dissipation performance is effectively improved by providing the second cavity 20z to expose the second surface 231b of the electronic component mounting pad 231 to the outside.

According to at least one embodiment, heat dissipation from an interconnect substrate incorporating an electronic component is effectively improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The disclosures herein non-exhaustively include the subject matter set out in the following clauses.

Clause 1. A method of making an interconnect substrate, comprising:

providing a core layer having one surface and another surface opposite the one surface, the core layer including an interconnect region to become an interconnect substrate and a cutting region to be severed at a time of making the interconnect substrate;

forming an interconnect layer including an electronic component mounting pad in the interconnect region on the another surface of the core layer;

forming a first cavity penetrating from the one surface to the another surface of the core layer to expose a first surface of the electronic component mounting pad; and

placing an electronic component on the first surface in the first cavity,

wherein the forming of the first cavity includes:

cutting through the core layer with a conductive cutting tool until the first surface is exposed; and

controlling a cutting depth of the cutting tool by detecting electrical conduction between the cutting tool and the electronic component mounting pad.

Clause 2. The method according to clause 1, wherein the forming of the interconnect layer includes forming a conduction terminal in the cutting region, the conduction terminal being electrically connected to the electronic component mounting pad, and

wherein the forming of the first cavity includes:

bringing a conduction jig into contact with the conduction terminal, the cutting jig being part of a cutting jig, the cutting jig including the conduction jig, the cutting tool, and a conduction detector for detecting electrical conduction between the conduction jig and the cutting tool;

lowering the cutting tool while cutting through the core layer and stopping the lowering when the conduction detector detects the electrical conduction; and

forming the first cavity by moving the cutting tool in directions parallel to the one surface of the core layer while the conduction detector is detecting the electrical conduction.

Clause 3. The method according to clause 2, further comprising:

laminating an insulating layer and a solder resist layer sequentially on the another surface of the core layer; and

forming a second cavity extending through the solder resist layer and the insulating layer to expose a second surface of the electronic component mounting pad opposite the first surface,

wherein the forming of the second cavity includes:

cutting through the solder resist layer and the insulating layer with the cutting tool until the second surface is exposed; and

controlling a cutting depth of the cutting tool by detecting electrical conduction between the cutting tool and the electronic component mounting pad.

What is claimed is:

1. An interconnect substrate comprising:
a core layer having one surface and another surface;
a first cavity extending from the one surface to the another surface of the core layer;
an electronic component mounting pad disposed on the another surface of the core layer and having a first surface serving as an end surface of the first cavity; and
an electronic component disposed on the first surface in the first cavity.

2. The interconnect substrate according to claim 1, further comprising:
an insulating layer and a solder resist layer sequentially laminated on the another surface of the core layer; and
a second cavity extending through the solder resist layer and the insulating layer to expose a second surface of the electronic component mounting pad opposite the first surface.

3. The interconnect substrate according to claim 2, further comprising a heatsink component disposed on the second surface in the second cavity.

4. The interconnect substrate according to claim 2, wherein the second cavity is located at an overlapping position with the first cavity in plan view.

5. The interconnect substrate according to claim 1, further comprising an insulating layer, an interconnect layer, and a solder resist layer sequentially laminated on the another surface of the core layer,
wherein the interconnect layer includes: a heatsink pad disposed on a surface of the insulating layer; and a via interconnect extending through the insulating layer to connect the heatsink pad and the electronic component mounting pad, and
wherein the solder resist layer includes an opening exposing the heatsink pad.

6. The interconnect substrate according to claim 1, further comprising an interconnect disposed on the another surface of the core layer, the interconnect being electrically connected to the electronic component mounting pad and having an end surface exposed on a same side as a lateral surface of the core layer.

7. The interconnect substrate according to claim 6, wherein the end surface of the interconnect is flush with the lateral surface of the core layer.
